(19) United States
(12) Patent Application Publication
(10) Pub. No.: US 2025/0308855 A1
(43) Pub. Date: Oct. 2, 2025

(54) STRUCTURAL MEMBER

(71) Applicant: TOTO LTD., Fukuoka (JP)

(72) Inventors: Morio HOSOKAWA, Fukuoka (JP); Tatsuya KOGA, Fukuoka (JP)

(21) Appl. No.: 19/077,871

(22) Filed: Mar. 12, 2025

(30) Foreign Application Priority Data
Mar. 28, 2024 (JP) 2024-052886
Jan. 29, 2025 (JP) 2025-013265

(51) Int. Cl. H01J 37/32

(52) U.S. Cl. CPC H01J 37/32495; H01J 37/32467; H01J 2237/0213

(57) ABSTRACT

A structural member 10 has a base material 100 and a protective film 200 covering the surface S1 of the base material 100. A roughness of the surface S1 of the base material 100 is a roughness with an average length RSm of 70 μm or more.

### CROSS-REFERENCE TO RELATED APPLICATION

This application is based upon and claims the benefit of priority from Japanese Patent Application No. 2024-052886 filed on Mar. 28, 2024, and Japanese Patent Application No. 2025-013265 filed on Jan. 29, 2025, the entire contents of which are incorporated herein by reference.

### FIELD

The present invention relates to a structural member.

### BACKGROUND

Structural members having a protective film on the surface of a base material are used in various fields such as semiconductor manufacturing equipment. For example, in a plasma etching system, a protective film is formed on the surface of a base material constructing an inner wall of a chamber for protecting the base material from plasma. For such a protective film, for example, oxide ceramics such as yttrium oxide (yttria) are used.

When the protective film is exposed to plasma, a part of the deteriorated protective film sputters in the form of large particles, likely affecting semiconductor manufacturing process. The protective film less likely causing such a phenomenon is notated hereinbelow as the “protective film with excellent particle proof.” For example, a protective film less likely causing the deterioration when exposed to plasma and a protective film that sputters when deteriorated in the form of fine particles to the extent of being not a problem in the process (that is, a protective film less likely forming large particles) are both considered the “protective film with excellent particle proof”.

The methods adaptable for forming the protective film on the surface of a base material include, for example, various film formation methods such as PVD and CVD. In recent years, the film formation by the aerosol deposition method has been increasingly practiced as described in Japanese Patent Laid-Open No. 2008-160097. Several film formation methods including the aerosol deposition method have achieved the formation of dense protective films composed of fine crystal grains with excellent particle proof, as described in Japanese Patent Laid-Open No. 2020-050536. The formation of a dense protective film with excellent particle proof requires longer film formation time than a conventional production method, however such a protective film can obtain a certain lifespan even when a thickness is comparatively thin. Thus, the study on comparatively thinning the thickness of protective films has been conducted. When the film thickness is thin, the shape of the protective film surface is more strongly affected by the surface shape of a base material.

### SUMMARY

For preventing the occurrence of particles, removal of unevenness on the protective film surface to reduce an arithmetic average roughness Ra and the like has been practiced. Additionally, for preventing the protective film from peeling and obtaining a dense protective film, it has been considered that the surface of a base material on which a protective film is formed needs to be a smooth surface having an arithmetic average roughness Ra of about 0.1 μm or less.

The present inventors have found that a structural member with excellent particle proof can be obtained by controlling the parameter of plane direction, instead of the arithmetic average roughness Ra, which is the parameter of height direction, on the surface of a base material on which the protective film is formed. An object of the present invention is to provide a structural member having a protective film with excellent particle proof.

For solving the above problem, the structural member according to the present invention has a base material and a protective film covering the surface of the base material. In the structural member, a surface roughness of the base material is a roughness with an average length RSm of 70 μm or more.

According to the experiment conducted by the present inventors, the surface of a base material having an average length RSm of 70 μm or more enables to obtain a structural member having a protective film with excellent particle proof even when, for example, the surface of the base material has an arithmetic average roughness Ra of more than 0.1 μm.

According to the present invention, the structural member having a protective film with excellent particle proof can be provided.

### BRIEF DESCRIPTION OF THE DRAWINGS

FIG. 1 schematically shows a cross-section of the structural member according to the present embodiment;

FIG. 2A illustrates the surface shape of a base material;

FIG. 2B illustrates the surface shape of a base material;

FIG. 3 shows the results of a film formation test;

FIG. 4 is an image obtained by capturing the surface of the base material using a laser microscope;

FIG. 5 is an image obtained by capturing the surface of the base material using a laser microscope; and

FIG. 6 is an image obtained by capturing the surface of the base material using a laser microscope.

### DETAILED DESCRIPTION

Hereinafter, the present embodiments will be described in reference to the attached drawings. For easier understanding of the descriptions, in the drawings, the same elements are denoted by the same reference signs as much as possible, and a duplicate description are not repeated.

The structural member 10 according to the present embodiment is used as, for example, the member constructing an inner wall of a processing chamber in a semiconductor manufacturing equipment (not shown in the figures) such as a plasma etching system. Such an application of the structural member 10 is only an example and is not limited to the semiconductor manufacturing equipment.

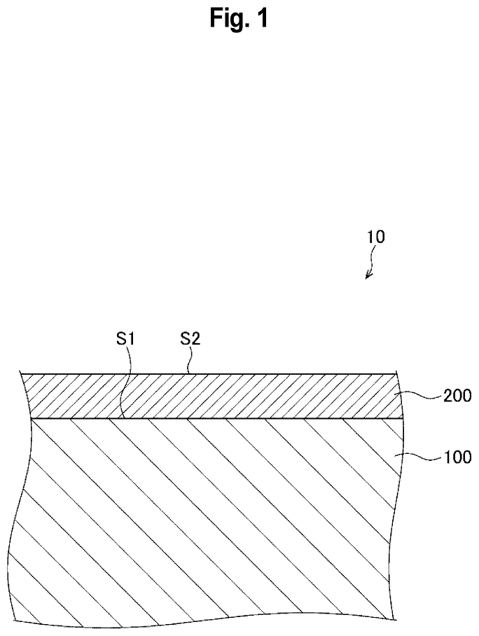

As shown in FIG. 1, the structural member 10 has a base material 100 and a protective film 200. In a plasma etching system and the like, the surface S2 of the protective film 200 is exposed toward the space in a chamber. The protective film 200 is provided for the purpose of protecting the surface S1 of the base material 100 from plasma.

The base material 100 is a member accounting for the majority of the structural member 10. In the present embodiment, the base material 100 is a ceramic sintered body containing a high purity aluminum oxide (Al₂O₃) but can also be formed of different types of ceramics from this. Alternatively, the base material 100 can also be formed of a material other than ceramics. The surface S1 of the base material 100 is a flat surface in the present embodiment, but the surface S1 can have a through-hole, an inclined plane or the like.

The protective film 200 is, as described above, the film formed to protect the base material 100 from plasma. The protective film 200 is formed in such a way as to cover throughout the entire surface S1 of the base material 100. In the present embodiment, the protective film 200 is constructed as a film containing a polycrystalline yttrium oxide (yttria: Y₂O₃), but can be a ceramics film composed of a different material. The thickness of the protective film 200 is suitably determined depending on the length of a period required to maintain the durability. In the present embodiment, the thickness of the protective film 200 is about 10 μm as an example, but can also be thinner.

The protective film 200 of the present embodiment is formed on the surface S1 of the base material 100 by the PVD method or the aerosol deposition method.

When an arithmetic surface roughness Ra of the surface S1 of the base material 100 is too high, it is known that the protective film 200 cannot be formed or the protective film peels. For this reason, for example, it is considered that the surface S1 needs to be a smooth surface in advance of the film formation. Conventionally, the surface S1 was polished and the like so that the surface S1 is a smooth surface having an arithmetic average roughness Ra of 0.1 μm or less. For polishing the surface S1 to achieve a smooth surface as described above, time and efforts are often required. Particularly, because the surface shape of the protective film is strongly affected by the surface shape of the base material when the thickness of the protective film is comparatively thin, it has been considered necessary to tightly manage the surface shape of the base material.

The present inventors have continued experiments and studies on the conditions satisfied by the shape of the surface S1 for forming the protective film 200. As a result, the inventors have obtained a novel finding that a structural member with excellent particle proof can be obtained by controlling the parameter of plane direction, instead of the arithmetic average roughness Ra, which is the parameter of height direction, of the surface S1 of the base material 100. Additionally, the surface S1 of the base material in the structural member can also have a root mean square slope Rdq of 15 μm or less.

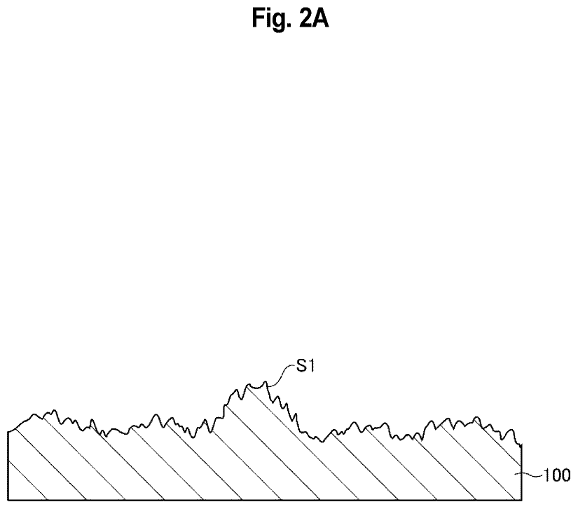

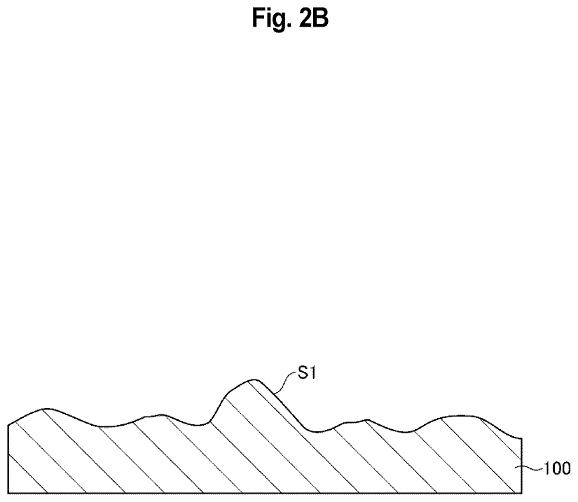

FIG. 2 schematically shows a cross-section of the base material 100 before the film formation. The “cross-section” referred herein means the cross-section when the base material 100 is cut along with the plane perpendicular to the surface S1.

The roughnesses of the surface S1 shown respectively in FIG. 2A and FIG. 2B are both approximately same roughness with each other in terms of the arithmetic average roughness Ra, which are specifically about Ra 0.40 μm. However, the surface S1 in FIG. 2B has fewer fine unevenness than the example in FIG. 2A. Such a difference in the shape does not appear as the difference in the arithmetic average roughness Ra, which is the parameter of height direction. For this reason, 2 of the surfaces S1 shown in FIG. 2 are both planes having Ra of 0.40 μm as described above despite the different shapes thereof from each other. On the other hand, the surface shapes of FIG. 2A and FIG. 2B are distinguishable in the average length RSm or root mean square slope Rdq, which is the parameter of plane direction.

The “average length RSm” refers to the average length of profile element in the roughness curve of cross-section as in FIG. 2. The “root mean square slope Rdq” is the parameter to evaluate the size of a local slope angle and refers to the root mean square of the local slope in the roughness curve of cross-section as in FIG. 2. The specific definitions and measurement methods of the average length RSm and root mean square slope Rdq are stipulated in JIS B 0601:2013.

In the example of FIG. 2A, the surface S1 has many fine unevenness, thereby making the length of the profile element described above shorter and making the value of average length RSm to be calculated less than 70 μm. It was revealed that when the surface of the base material in the structural member has the shape of FIG. 2A, the protective film peels and the density of protective film reduces, thereby causing insufficient particle proof of the structural member. Additionally, the root mean square slope Rdq of the surface S1 becomes more than 15 μm.

On the other hand, in the example of FIG. 2B, the surface S1 has fewer fine unevenness, thereby making the length of the profile element described above longer and making the value of average length RSm to be calculated more than 70 μm. It was revealed that when the surface of the base material in the structural member has the shape of FIG. 2B, the peel of the protective film and the reduction in the density of protective film can be prevented, thereby obtaining the structural member with high particle proof. That is, it was found to be useful to control RSm to be a predetermined value or less, instead of the arithmetic average roughness Ra, of the base material surface in the structural member of FIG. 2B. Additionally, the root mean square slope Rdq of the surface S1 becomes as low as 15 μm or less.

The present inventors made 3 samples of the base material 100 having different surface S1 shapes from each other and prepared structural members having the protective films 200 formed on the surface S1, respectively. The base material 100 was an alumina base material, and the protective film was a yttria film. At the fracture surface of the structural member, the surface S1 of each base material was measured for the arithmetic average roughness Ra, average length RSm and root mean square slope Rdq. Additionally, before the film formation, respective surfaces S1 were measured for the arithmetic average roughness Ra, average length RSm and root mean square slope Rdq, but in the present test, the surface shapes of the base materials in the structural members (after the protective film formation) were approximately the same as the surface shapes of the base materials before the film formation.

The arithmetic average roughness Ra, average length RSm and root mean square slope Rdq of the base material surface in the structural member are measured by a known method such as a method of calculating from a cross-section profile of the base material surface obtained from the cross-section of a sample, a method of measuring the surface roughness using a white light interferometry or a confocal laser scanning microscope, or a method of measuring a base material itself before the film is attached using a laser microscope or a contact-type surface roughness tester. As an example, a predetermined range of the surface S1 to be measured was captured using a laser microscope. The laser microscope used was KEYENCE VK-X3000. The objective lens used was of ×50 magnification, and images at ×1000 magnification were obtained, respectively.

Subsequently, the arithmetic average roughness Ra, average length RSm and root mean square slope Rdq were calculated respectively from the profile data (the data showing the shape of the surface S1 at the cross-section as in FIG. 2) obtained from the above images. The “sampling length” referring the measurement range was set to 250 μm. Additionally, the cut-off λs was set to 0.8 μm to calculate in the stylus mode. At that time, the stylus tip radius was set to 2 μm, and the stylus tip angle was set to 60°. The measurement was respectively carried out at 20 spots different from each other on the surface S1, and the obtained values were averaged, thereby calculating the arithmetic average roughness Ra, average length RSm and root mean square slope Rdq, respectively.

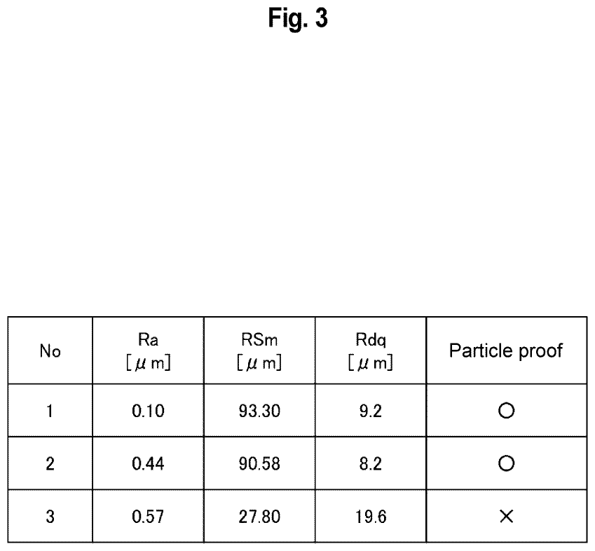

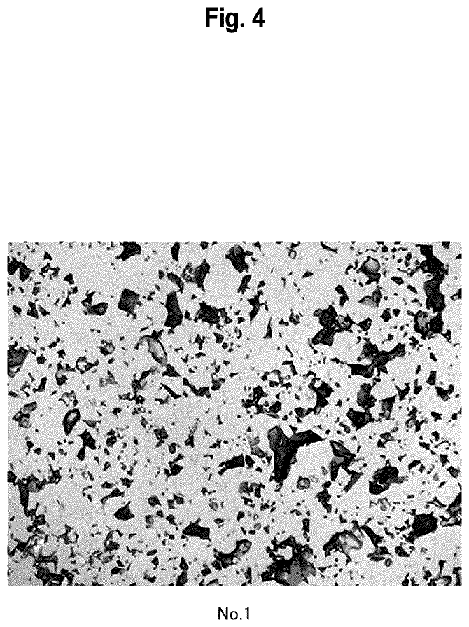

FIG. 3 shows the evaluation results. In the sample of No. 1, the surface S1 was subjected to surface grinding processing before the film formation and then was further subjected to LAP polishing. The surface S1 of the base material of this sample after the protective film formation had an arithmetic average roughness Ra of 0.10 μm, an average length RSm of 93.30 μm, and a root mean square slope Rdq of 9.2 μm. FIG. 4 shows the image obtained by capturing the surface S1 of the sample of No. 1 using a laser microscope.

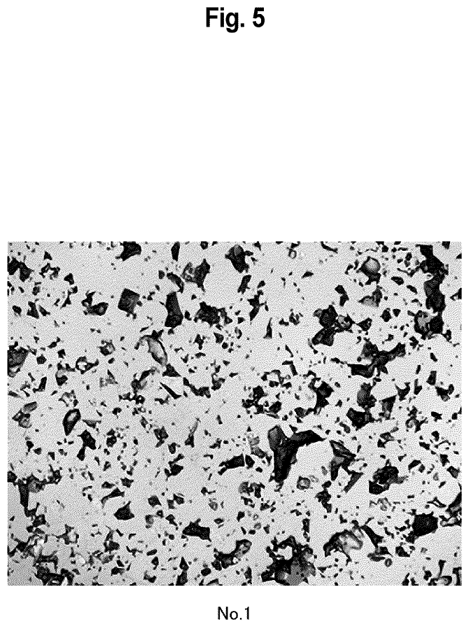

In the sample of No. 2, the surface S1 was subjected to surface grinding processing before the film formation and then was subjected to loose abrasive processing using finer abrasive grains to the extent of not removing the grinding waviness. The surface S1 of the base material of this sample after the protective film formation had an arithmetic average roughness Ra of 0.44 μm, an average length RSm of 90.58 μm, and a root mean square slope Rdq of 8.2 μm. FIG. 5 shows the image obtained by capturing the surface S1 of the sample of No. 2 using a laser microscope.

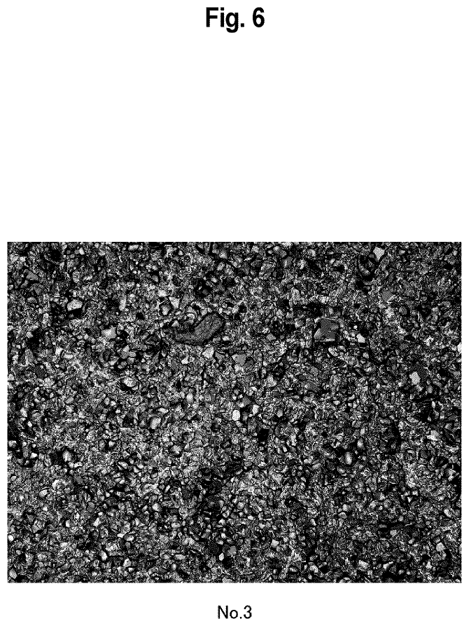

In the sample of No. 3, the surface S1 was subjected only to surface grinding processing before the film formation. The surface S1 of the base material of this sample after the protective film formation had an arithmetic average roughness Ra of 0.57 μm, an average length RSm of 27.80 μm, and a root mean square slope Rdq of 19.6 μm. FIG. 6 shows the image obtained by capturing the surface S1 of the sample of No. 3 using a laser microscope.

As shown in FIG. 3, both samples of No. 2 and 3 have the roughnesses of more than 0.1 μm in terms of the arithmetic average roughness Ra, which is the parameter of height direction.

In the sample of No. 2, the surfaces S1 have an average length RSm of as high as 90 μm or more respectively and have fewer fine unevenness as in the example of FIG. 2A. In contrast, in the sample of No. 3, the surface S1 has an average length RSm of as low as less than about 30 μm in addition to an arithmetic average roughness Ra of as high as 0.1 μm or more, with the presence of many fine unevenness as in the example of FIG. 2A, whereby the structural member of No. 3 had the result of poorer particle proof than No. 1 and No. 2. On the other hand, no significant difference was found between the particle proof of the sample of No. 1 having the arithmetic average height Ra of as low as about 0.1 μm and the particle proof of the sample of No. 2 having the arithmetic average height of as high as more than about 0.1 μm.

Thus, it was verified that even when the sample with the surface S1 having an arithmetic average roughness Ra of more than 0.1 μm, high particle proof in the structural member can be achieved as long as the surface S1 has a sufficiently high average length RSm. An experiment separately conducted by the present inventors verifies that when the roughness of the surface S1 in the structural member has an average length RSm of 70 μm or more, the particle proof becomes satisfactory.

The processing method for achieving the roughness of the surface S1 having an average length RSm of 70 μm or more can adopt known various methods. Examples include grindstone polishing, lapping polishing, buff polishing, barrel polishing, electropolishing, and sandblast polishing. When the kind and size of an abrasive used for polishing are suitably selected and the polishing time is adjusted, the average length RSm of the surface S1 can achieve 70 μm or more before the arithmetic average roughness Ra of the surface S1 reaches 0.1 μm or less. This also enables to simplify the surface treatment of the base material 100 before the film formation compared to a case where the process is carried out until the arithmetic average roughness Ra of the surface S1 reaches 0.1 μm or less, thereby enhancing the productivity.

Even when the surface S1 of the base material 100 is not a flat surface and is a non-flat surface, for example, a curved surface, the average length RSm and the like of the surface S1 may be measured. When the surface S1 is a non-flat surface, the average length RSm and the like can be measured by, for example, a method as described below.

First, a part of the base material 100 is cut out to prepare a plate-like sample including the surface S1 which is a non-flat surface. This sample may be prepared, for example, so as to have the surface S1 throughout its principal surface and have a size of 20 mm×20 mm. A part of the base material 100 is cut out as such a small piece of a sample, whereby the surface S1 to be measured can be rendered flatter and, for example, surface observation under a laser microscope can be easily performed.

If the cut out surface S1 can be roughly regarded as a flat surface, the size of the sample may be different from the size described above. For example, when the surface S1 of the base material 100 has a curved shape, and the radius of curvature of which is relatively large, the base material 100 may be cut out into a sample having a relatively large size. On the other hand, when a part of the surface S1 has a relatively small radius of curvature, a sample can be prepared by cutting the base material 100 so as to exclude this part.

The small piece of the sample as described above is prepared and may then be subjected to the measurement of the average length RSm and the like of the surface S1 by the same methods as those described above.

Even if a part or the whole of the surface S1 is a curved surface, observation may be rarely affected by the shape of the surface S1 and be achieved as long as the magnification power of measurement under a laser microscope is about 1000×. If the influence of the shape of the surface S1 is a concern, slope correction or background correction can be appropriately carried out according to the need.

If the sample vibrates during measurement, it is difficult to accurately measure the average length RSm and the like of the surface S1. Accordingly, a ground contact surface in the sample, that is, a surface on the side opposite to the surface S1, can be processed so as to have a shape that permits stable placement (for example, a flat surface). This suppresses the vibration of the sample and enables the average length RSm and the like of the surface S1 to be measured with high precision.

Hereinabove, the present embodiment has been described in reference to the specific examples. However, the present disclosure is not limited to these specific examples. Embodiments in which suitable design modifications are added to these specific examples by a person skilled in the art are also encompassed in the scope of the present disclosure as long as the features of the present disclosure are provided. Each element and the arrangements, conditions and shapes thereof included in each specific example described earlier are not limited to those given as examples and can be suitably modified. Each element included in each specific example described earlier can suitably have different combinations as long as technical contradictions do not arise.

What is claimed is:

1. A structural member comprising:
a base material, and
a protective film covering a surface of the base material,
wherein a roughness of the surface is a roughness with an average length RSm of 70 μm or more.

2. The structural member according to claim 1, wherein the roughness of the surface is a roughness with a root mean square slope Rdq of 15 μm or less.

3. The structural member according to claim 1, wherein the roughness of the surface is a roughness with an arithmetic average roughness Ra of more than 0.1 μm.

4. The structural member according to claim 2, wherein the roughness of the surface is a roughness with an arithmetic average roughness Ra of more than 0.1 μm.

5. The structural member according to claim 1, wherein the base material is formed of a material containing aluminum oxide.

6. The structural member according to claim 1, wherein the protective film is formed of a material containing yttrium oxide.

7. The structural member according to claim 1, wherein the protective film is formed by an aerosol deposition method.
